(19) United States
(12) Patent Application Publication
(10) Pub. No.: US 2025/0085350 A1
(43) Pub. Date: Mar. 13, 2025

(54) ANOMALY DETECTOR, MOTOR SYSTEM, AND METHOD FOR DETECTING ANOMALY

(71) Applicant: MINEBEA MITSUMI Inc., Nagano (JP)

(72) Inventors: Susumu TERAOKA, Nagano (JP); Hiroyuki KAIDU, Nagano (JP); Masato AOKI, Nagano (JP)

(21) Appl. No.: 18/817,650

(22) Filed: Aug. 28, 2024

(30) Foreign Application Priority Data
Sep. 7, 2023 (JP) 2023-145195

(51) Int. Cl. G01R 31/34

(52) U.S. Cl. CPC G01R 31/343

(57) ABSTRACT

An anomaly detector for detecting an anomaly of a motor includes circuitry configured to acquire a characteristic value related to the motor and process the characteristic value. The circuitry is configured to acquire the characteristic value related to the motor as inspection data, update a statistic of the inspection data, update an amplitude from an updated statistic, update an exponential moving average value of the inspection data, update an anomaly level based on the inspection data, the amplitude, the statistic, and the exponential moving average value, and detect the anomaly of the motor based on the anomaly level.

### CROSS-REFERENCE TO RELATED APPLICATIONS

This application claims priority under 35 U.S.C. § 119 to Japanese Patent Application No. 2023-145195, filed Sep. 7, 2023, the contents of which are incorporated herein by reference.

### BACKGROUND

### 1. Technical Field

The present disclosure relates to an anomaly detector, a motor system, and a method for detecting an anomaly.

### 2. Description of the Related Art

Patent Document 1 discloses an abnormality determination apparatus for determining a mechanical abnormality of a motor drive mechanism. The abnormality determination apparatus disclosed in Patent Document 1 includes a data abnormality determination unit for determining a data abnormality of time series data, and includes a mechanical abnormality determination unit for determining the mechanical abnormality of the motor drive mechanism based on an acquisition mode of the time series data determined as the data abnormality.

### RELATED-ART DOCUMENT

### Patent Document

Patent Document 1: Japanese Unexamined Patent Application Publication No. 2017-151598

### SUMMARY

In one aspect of the present disclosure, an anomaly detector for detecting an anomaly of a motor is provided. The anomaly detector includes circuitry configured to acquire a characteristic value related to the motor and process the characteristic value. The circuitry is configured to acquire the characteristic value related to the motor as inspection data, update a statistic of the inspection data, update an amplitude from an updated statistic, update an exponential moving average value of the inspection data, update an anomaly level based on the inspection data, the amplitude, the statistic, and the exponential moving average value, and detect the anomaly of the motor based on the anomaly level.

### BRIEF DESCRIPTION OF THE DRAWINGS

FIG. 1 is a diagram schematically showing a motor system including a motor controller according to the present embodiment.

FIG. 2 is a flowchart for describing the process by the motor controller according to the present embodiment.

FIG. 3 is a diagram for describing an operation result by the motor controller according to the present embodiment.

FIG. 4 is a diagram for describing the operation result by the motor controller according to the present embodiment.

FIG. 5 is a diagram for describing the operation result by the motor controller according to the present embodiment.

FIG. 6 is a diagram for describing the operation result by the motor controller according to the present embodiment.

FIG. 7 is a diagram for describing the operation result by the motor controller according to the present embodiment.

FIG. 8 is a diagram for describing the operation result by the motor controller in a reference example.

FIG. 9 is a diagram for describing the operation result by the motor controller according to the present embodiment.

FIG. 10 is a diagram for describing the operation result by the motor controller according to the present embodiment.

FIG. 11 is a diagram for describing the operation result by the motor controller in the reference example.

FIG. 12 is a diagram for describing the operation result by the motor controller in the reference example.

### DETAILED DESCRIPTION

The inventors of the present application have recognized the following information in related art. In general, anomaly detection algorithms detect data variations. In this case, for example, if a rotational speed of a variable speed motor deliberately changes, anomalies may be erroneously detected. Also, in an environment where a motor is installed, if there are gradual changes in the environment, anomalies may be erroneously detected.

The present disclosure provides an anomaly detector that suppresses false detection when performing anomaly detection of a motor.

### <Motor System>

Hereinafter, a motor system including a motor controller according to the present embodiment will be described with reference to the drawings.

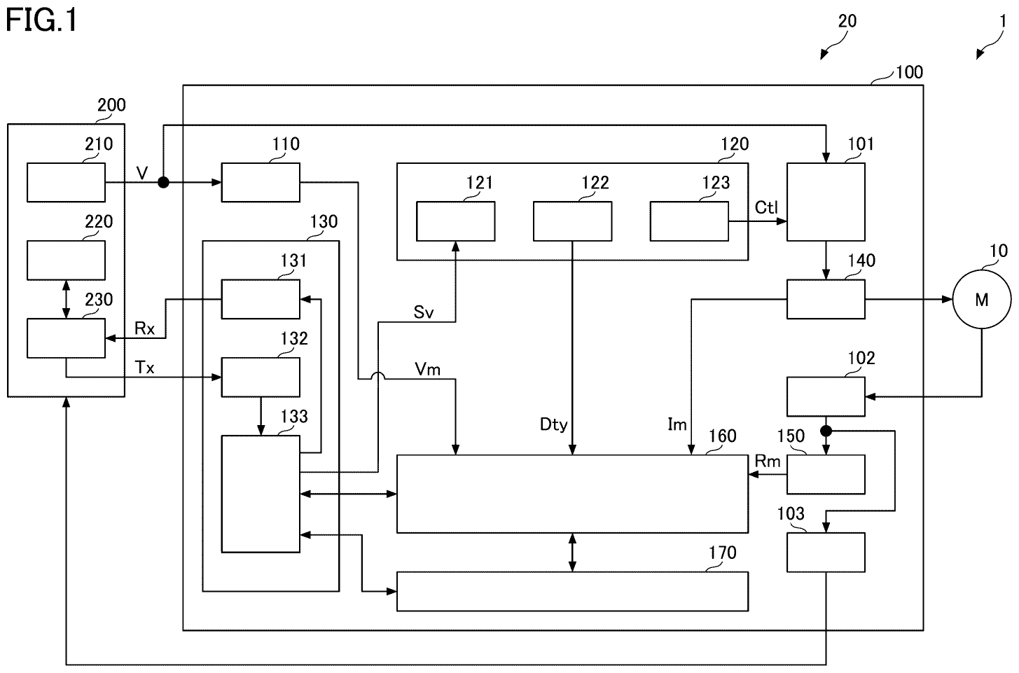

FIG. 1 is a diagram schematically showing a motor system 1 including a motor controller 100 that is used as an example of the motor controller according to the present embodiment. The motor controller 100 is an example of an anomaly detector for detecting an anomaly of a motor.

The motor system 1 includes a motor 10 and a motor drive control system 20. The motor 10 is used for rotating a fan, for example. The motor drive control system 20 drives and controls the motor 10.

The motor drive control system 20 includes the motor controller 100 and a host device 200.

### <Motor Controller 100>

The motor controller 100 includes a motor driver circuit 101, a sensor unit 102, and a frequency generator (FG) signal generator 103. The motor controller 100 also includes a power supply voltage measuring unit 110, a drive control signal generator 120, a communication unit 130, a current measuring unit 140, a rotational speed measuring unit 150, an anomaly detection controller 160, and a data management unit 170.

The drive control signal generator 120, the rotational speed measuring unit 150, the anomaly detection controller 160, and the data management unit 170 in the motor controller 100 are implemented by, for example, a program processing device (computer). More specifically, the program processing device includes a processor such as a central processing unit (CPU), and includes various storage devices such as a random access memory (RAM) and a read only memory (ROM). The program processing device also includes peripheral circuits such as a counter (timer), an analog-to-digital (AD) conversion circuit, a digital-to-analog (DA) conversion circuit, a clock generation circuit, and an input/output interface (I/F) circuit. For example, the processor, the storage devices, and the peripheral circuits are connected to one another via a bus or a dedicated line. The program processing device is, for example, a microcontroller. In the program processing device, the CPU executes various kinds of arithmetic processing according to a program that is stored in a memory, to thereby perform processing.

### [Motor Driver Circuit 101]

The motor driver circuit 101 drives the motor 10 based on a drive control signal Ctl that is generated by the drive control signal generator 120. The motor driver circuit 101 includes, for example, a pre-driver circuit and an inverter circuit.

The pre-driver circuit generates an output signal to drive the inverter circuit based on the drive control signal Ctl. The pre-driver circuit outputs the generated output signal to the inverter circuit. The pre-driver circuit generates and outputs a drive signal to drive each switching element in the inverter circuit, based on, for example, the drive control signal Ctl.

The inverter circuit outputs a drive signal to the motor 10 based on the output signal that is output from the pre-driver circuit. The drive signal output from the inverter circuit energizes one or more coils that are provided in the motor 10. In the inverter circuit, for example, two switching elements that are provided at both ends of a DC power source, for example, a pair of series circuits that include transistors, such as field effect transistors is connected to a coil for each phase. Each phase terminal of the motor 10 is connected to a connection point of two switching elements in the pair of switching elements.

The drive signal generated by the pre-driver circuit turns on and off switching elements that constitute the inverter circuit. In this arrangement, power is provided for each phase of the motor 10 and thus a rotor of the motor 10 rotates.

The power from a power source 210 that is provided in the host device 200 is delivered to the motor driver circuit 101. The motor driver circuit 101 is connected to the power source 210 provided in the host device 200. The motor driver circuit 101 converts the power provided from the power source 210 based on the drive control signal Ctl. The motor driver circuit 101 then delivers the converted power to the motor 10.

### [Sensor Unit 102]

The sensor unit 102 detects a rotational position of the rotor of the motor 10. The sensor unit 102 includes, for example, a position sensor. The sensor unit 102 includes, for example, a Hall element. The Hall element of the sensor unit 102 detects a magnetic pole of the rotor. The Hall element of the sensor unit 102 outputs a Hall signal whose voltage changes according to the rotation of the rotor.

The position sensor of the sensor unit 102 is not limited to the Hall element. As the position sensor, any sensor capable of detecting the rotational position of the rotor in the motor may be used. An encoder or the like may be used as the position sensor. When the encoder is used as the position sensor, the sensor unit 102 may be provided outside the motor controller 100 as an individual device that is separated from the motor controller 100. That is, the sensor unit 102 is not used as one of components in the motor controller 100.

### [FG Signal Generator 103]

The FG signal generator 103 generates the FG signal as a rotational speed signal indicating the rotational speed of the motor 10. For example, the FG signal generator 103 generates a signal (FG signal) having a period (frequency) proportional to the rotational speed of the motor 10, based on a detection signal (Hall signal) that is output from the Hall element of the sensor unit 102. The FG signal output from the FG signal generator 103 is input to the host device 200. The FG signal generator 103 may be implemented by, for example, an FG pattern that is formed on a substrate (printed circuit board) on which the motor 10 is mounted.

### [Power Supply Voltage Measuring Unit 110]

The power supply voltage measuring unit 110 measures a voltage V of the power provided from the host device 200. In other words, the power supply voltage measuring unit 110 measures the power supply voltage. The power supply voltage measuring unit 110 outputs a measured voltage magnitude Vm to the anomaly detection controller 160.

### [Drive Control Signal Generator 120]

The drive control signal generator 120 generates the drive control signal Ctl to control the drive of the motor 10. The drive control signal generator 120 receives, for example, a speed command signal Sv that is a drive command signal that is output from the host device 200 as a drive command. When the drive control signal generator 120 receives a speed command signal Sv, the drive control signal generator 120 generates the drive control signal Ctl such that the rotational speed of the motor 10 matches a target rotational speed that is specified by the speed command signal Sv.

The drive control signal Ctl is, for example, a pulse width modulation (PWM) signal.

The drive control signal generator 120 includes a speed command analysis unit 121, a duty cycle determination unit 122, and an energization controller 123.

### (Speed Command Analysis Unit 121)

The speed command analysis unit 121 receives the speed command signal Sv output from the host device 200. Then, the speed command analysis unit 121 analyzes a target rotational speed that is specified by the speed command signal Sv. For example, when the speed command signal Sv is a PWM signal having a duty cycle that corresponds to the target rotational speed, the speed command analysis unit 121 analyzes the duty cycle of the speed command signal Sv, and outputs information on the rotational speed that is derived from the duty cycle, as the target rotational speed.

### (Duty Cycle Determination Unit 122)

The duty cycle determination unit 122 determines the duty cycle of the PWM signal as the drive control signal Ctl, based on (i) the target rotational speed output from the speed command analysis unit 121 and (ii) a measurement value of the rotational speed of the motor 10 measured by the rotational speed measuring unit 150.

Specifically, the duty cycle determination unit 122 calculates a control value of the motor 10 such that a difference between the target rotational speed and the measured value of the rotational speed of the motor 10 becomes smaller. Then, the duty cycle determination unit 122 determines the duty cycle of the PWM signal according to the calculated control value. For example, the duty cycle determination unit 122 calculates the control value by proportional-integral-differential (PID) control such that the difference between the target rotational speed and a measured value of the rotational speed of the motor 10 becomes smaller. The duty cycle determination unit 122 may calculate the control value by either proportional-differential (PD) control or proportional-integral (PI) control. Then, the duty cycle determination unit 122 determines a duty cycle Dty of the PWM signal according to the control value.

The duty cycle determination unit 122 outputs a determined duty cycle Dty to the anomaly detection controller 160.

### (Energization Controller 123)

The energization controller 123 generates the PWM signal having the duty cycle determined by the duty cycle determination unit 122. Then, the energization controller 123 outputs the generated PWM signal to the motor driver circuit 101 as the drive control signal Ctl.

### [Communication Unit 130]

The communication unit 130 communicates with an external device. The communication unit 130 communicates with the host device 200. Specifically, the communication unit 130 transmits and receives data with respect to the host device 200 that is used as a controller. The communication unit 130 includes a transmitter 131, a receiver 132, and a communication controller 133.

The transmitter 131 transmits data to the host device 200. The receiver 132 receives data from the host device 200. The transmitter 131 and the receiver 132 are controlled by the communication controller 133. The transmitter 131 is, for example, a serial communication interface circuit that generates a predetermined serial signal and transmits the predetermined serial signal to a communication line. The receiver 132 is, for example, a serial communication interface circuit that receives the predetermined serial signal from the communication line.

The communication controller 133 controls the transmitter 131 and the receiver 132. The communication controller 133 sends encoded data to the transmitter 131. The communication controller 133 decodes data received from the receiver 132. The communication controller 133 transmits and receives data with respect to the host device 200 by controlling the transmitter 131 and the receiver 132. The communication controller 133 is implemented, for example, by a program executed by a processor that is provided in the motor controller 100.

The communication controller 133 receives the speed command signal Sv that is output from the host device 200, as a drive command. The communication controller 133 transmits the received speed command signal Sv to the speed command analysis unit 121.

### [Current Measuring Unit 140]

The current measuring unit 140 measures the current of the power provided from the motor driver circuit 101 to the motor 10. The current measuring unit 140 includes, for example, a current transformer. The current measuring unit 140 outputs, to the anomaly detection controller 160, a current magnitude Im that is obtained by measuring the current of the power provided from the motor driver circuit 101 to the motor 10.

### [Rotational Speed Measuring Unit 150]

The rotational speed measuring unit 150 measures the rotational speed of the motor 10. The rotational speed measuring unit 150 measures the rotational speed of the motor 10 based on the detection signal (Hall signal) from the Hall element in the sensor unit 102, for example. The rotational speed measuring unit 150 outputs a measured rotational speed Rm to the anomaly detection controller 160.

### [Anomaly Detection Controller 160]

The anomaly detection controller 160 detects an anomaly of the motor 10. The anomaly detection controller 160 estimates and detects the occurrence of the anomaly of the motor 10 based on any one among the voltage magnitude Vm, the current magnitude Im, the rotational speed Rm of the motor 10, and the duty cycle Dty.

### [Data Management Unit 170]

The data management unit 170 manages data.

### <Host Device 200>

Hereinafter, the host device 200 will be described. The host device 200 provides power to the motor controller 100. The host device 200 also instructs the motor controller 100 about the rotational speed. The host device 200 includes the power source 210, a data processing controller 220, and a communication unit 230.

### [Power Source 210]

The power source 210 provides the power for operating the motor 10 to the motor controller 100. The power source 210 is a DC power source. The power source 210 provides, for example, the power of 12 V (volts) to the motor controller 100.

### [Data Processing Controller 220]

The data processing controller 220 instructs the motor controller 100 about the target rotational speed (target rotational speed) of the motor 10. The data processing controller 220 transmits the speed command signal Sv to the motor controller 100 via the communication unit 230. The data processing controller 220 transmits the speed command signal Sv to the motor controller 100, thereby to instruct the motor controller 100 about the target rotational speed (target rotational speed).

### [Communication Unit 230]

The communication unit 230 communicates with the motor controller 100. The communication unit 230 communicates with the communication unit 130 in the motor controller 100. The communication unit 230 receives a signal that is transmitted from the transmitter 131 in the communication unit 130, as a reception signal Rx. The communication unit 230 also transmits a transmission signal Tx to the receiver 132 in the communication unit 130. The communication unit 230 is, for example, a serial communication interface circuit that generates a predetermined serial signal and that transmits and receives the serial signal from the communication line.

### <Process by Anomaly Detection Controller>

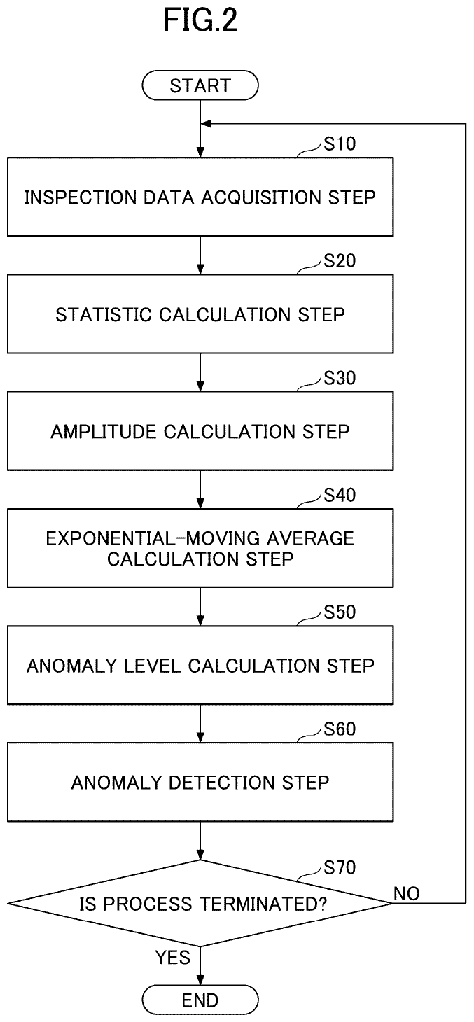

Hereinafter, the process by the anomaly detection controller 160 will be described. While describing the process by the anomaly detection controller 160, steps included in a motor anomaly detection method for detecting the anomaly of the motor 10 will be described. Here, the motor anomaly detection method is executed by the motor controller 100. Also, a procedure of the program executed by a computer provided in the motor controller 100 will be described below. FIG. 2 is a flowchart for describing the process by the motor controller 100 that is an example of a motor controller according to the present embodiment.

In order to detect the anomaly of the motor 10, the inventors of the present application have found that for a characteristic value related to the motor 10 during operation, false detection can be suppressed by calculating the standard deviation as a statistic and by calculating the amplitude using the standard deviation.

The anomaly detection controller 160 in the motor controller 100 performs an inspection data acquisition step (step S10), a statistic calculation step (step S20), and an amplitude calculation step (step S30). Subsequently, the anomaly detection controller 160 performs a moving average calculation step (step S40), an anomaly level calculation step (step S50), and an anomaly detection step (step S60). The anomaly detection controller 160 repeatedly performs steps S10 to S60 while the motor 10 is operating.

### (Step 10)

While the motor 10 is operating, the anomaly detection controller 160 acquires one or more sampled characteristic values of the motor 10 as inspection data (inspection data acquisition step). The characteristic value of the motor 10 includes, for example, any one among a current magnitude and a voltage magnitude of the power provided to the motor 10, the rotational speed of the motor 10, and the duty cycle.

In this example, inspection data that is acquired nth by the anomaly detection controller 160 is expressed by inspection data xi(n), where n is an integer of 1 or more.

### (Step 20)

Next, the anomaly detection controller 160 calculates a statistic using acquired inspection data (statistic calculation step). The anomaly detection controller 160 calculates a standard deviation of the inspection data that is used as an example of a statistic. In order to calculate the standard deviation, the anomaly detection controller 160 calculates an average of the inspection data and an average (mean square) of values that are obtained by squaring the inspection data.

A specific calculation method will be described below. The anomaly detection controller 160 updates and calculates an nth average Xa(n) using nth inspection data xi(n) and (n−1)th average Xa(n−1), as expressed in Equation 1. In the equation, N is an integer of 2 or more. For example, N is an integer from 100 to 1,000.

$$\begin{matrix}[ Math . 1 ] & \\ Xa ( n ) = \frac{1}{N + 1} ( NXa ( n - 1 ) + xi ( n ) ) & Equation 1\end{matrix}$$

The anomaly detection controller 160 calculates nth mean square Xsa(n) using the nth inspection data xi(n) and an (n−1)th mean square Xsa(n−1), as expressed in Equation 2.

$$\begin{matrix}[ Math . 2 ] & \\ Xsa ( n ) = \frac{1}{N + 1} ( N X s a ( n - 1 ) + x {i ( n )}^{2} ) & Equation 2\end{matrix}$$

Here, the mean square Xsa(n) corresponds to the average of values obtained by squaring inspection data xi, as expressed in Equation 3.

$$\begin{matrix}[ Math . 3 ] & \\ X sa ( n ) \approx \overline{{xi}^{2}} = \frac{1}{N + 1} {\sum }^{N + 1} x {i ( n )}^{2} & Equation 3\end{matrix}$$

Then, the anomaly detection controller 160 calculates a nth standard deviation σi(n) using the nth average Xa(n) and the mean square Xsa(n), as expressed in Equation 4.

$$\begin{matrix}[ Math . 4 ] & \\ σ i ( n ) = \sqrt{X s a ( n ) - X {a ( n )}^{2}} & Equation 4\end{matrix}$$

When calculating the standard deviation, in a case where the standard deviation is calculated using variance for a set of data, it is necessary to temporarily store data used for calculation. If an amount of data is increased, an area where data is stored becomes larger, and as a result, memory consumption may be increased.

In view of the above situation, the anomaly detection controller 160 calculates the average and the mean square by using recurrence relations (exponential moving average) as expressed in Equations 1 and 2, and thereby calculates the standard deviation. The standard deviation can be obtained by a sequential computation that utilizes the recurrence relations (exponential moving average), and thus the memory consumption can be reduced.

### (Step S30)

Next, the anomaly detection controller 160 calculates an amplitude Ri at the time of anomaly based on the statistic calculated in step S20 (amplitude calculation step). Specifically, the anomaly detection controller 160 updates and calculates an nth amplitude Ri(n) as expressed in Equation 5 that uses the nth standard deviation σi(n).

$$\begin{matrix}[ Math . 5 ] & \\ R i ( n ) = 3 \times σ i ( n ) & Equation 5\end{matrix}$$

### (Step S40)

Next, the anomaly detection controller 160 updates an exponential moving average value of the inspection data acquired in step S10 (moving average calculation step).

The anomaly detection controller 160 calculates the exponential moving average value of the inspection data. Here, the exponential moving average value that is acquired nth is expressed as an exponential moving average value yi(n). The exponential moving average value yi(n) acquired nth is calculated as expressed in Equation 6 using a smoothing factor α, the nth inspection data xi(n), and the exponential moving average value yi(n−1) that is acquired (n−1)th. Here, a is a constant of greater than or equal to zero and less than or equal to 1.

$$\begin{matrix}[ Math . 6 ] & \\ y i ( 1 ) = α xi ( n ) + ( 1 - α ) yi ( n - 1 ) & Equation 6\end{matrix}$$

The exponential moving average value yi(n) is calculated by the sum of a value obtained by multiplying the smoothing factor α by the inspection data xi(n), and a value obtained by multiplying a value obtained by subtracting the smoothing factor α from 1, by the exponential moving average value yi(n−1). In other words, the exponential moving average value yi(n) is updated to a value obtained by the sum of (i) the value obtained by multiplying the smoothing factor α by the inspection data xi(n) and (ii) the value obtained by multiplying the value that is obtained by subtracting the smoothing factor α from 1, by the exponential moving average value yi(n−1).

The anomaly detection controller 160 may calculate the exponential moving average value yi(n) as expressed in Equation 7, instead of Equation 6. The anomaly detection controller 160 may calculate the exponential moving average value yi(n) that is acquired nth, as expressed in Equation 7 that uses the smoothing factor N, nth inspection data xi(n), and the (n−1)th exponential moving average value yi(n−1). In other words, the anomaly detection controller 160 may calculate the exponential moving average value yi(n) based on the smoothing factor α that is expressed by 1/(N+1). Here, N is an integer of 2 or more. For example, N is an integer from 100 to 1,000. In this description, N may express the smoothing factor.

$$\begin{matrix}[ Math . 7 ] & \\ y i ( n ) = \frac{1}{N + 1} ( x i ( n ) + N y i ( i - 1 ) ) & Equation 7\end{matrix}$$

The exponential moving average yi(n) is updated to a value obtained by dividing, by a value obtained by adding 1 to the smoothing factor N, the sum of the inspection data xi(n) and a value obtained by multiplying the exponential moving average yi(n−1) by the smoothing factor N.

### (Step S50)

Next, the anomaly detection controller 160 updates an anomaly level based on the inspection data xi(n), the amplitude Ri(n), the standard deviation σi(n), and the exponential moving average value yi(n) (anomaly level calculation step). The anomaly detection controller 160 updates the anomaly level based on the inspection data xi(n) acquired in step S10, the standard deviation σi(n) calculated in step S20, the amplitude Ri(n) calculated in step S30, and the exponential moving average value yi(n) calculated in step S40. The anomaly detection controller 160 calculates a change level Sd(n) as expressed in Equation 8.

$$\begin{matrix}[ Math . 8 ] & \\ Sd ( n ) = \frac{R i ( n ) ( x i ( n ) - y i ( n - 1 ) - \frac{R i ( n )}{2} )}{σ {i ( n )}^{2}} & Equation 8\end{matrix}$$

The anomaly detection controller 160 calculates an anomaly level Se(n) as expressed in Equation 9.

$$\begin{matrix}[ Math . 9 ] & \\ Se ( n ) = max \{ 0 , Se ( n - 1 ) + S d ( n ) \} & Equation 9\end{matrix}$$

Here, max{a,b} is a function that returns a greater value of a and b. That is, when a result obtained by Se(n−1)+Sd(n) is negative or zero, max{0,Se(n−1)+Sd(n)} indicates zero, and when “Se(n−1)+Sd(n)” is positive, max{0, Se(n−1)+Sd(n)} returns “Se(n−1)+Sd(n).”

### (Step S60)

Next, the anomaly detection controller 160 detects an anomaly of the motor 10 based on the anomaly level Se(n) (anomaly detection step). When the anomaly level Se(n) is greater than a predetermined threshold, the anomaly detection controller 160 detects that the anomaly occurs in the motor 10.

### (Step S70)

The anomaly detection controller 160 determines whether to terminate the process. If the process is terminated (YES in step S70), the anomaly detection controller 160 terminates the process. If the process is not terminated, in other words, if the process is continuously performed (NO in step S70), the anomaly detection controller 160 returns to step S10 and repeats the process.

### <Operation Results by Motor Controller>

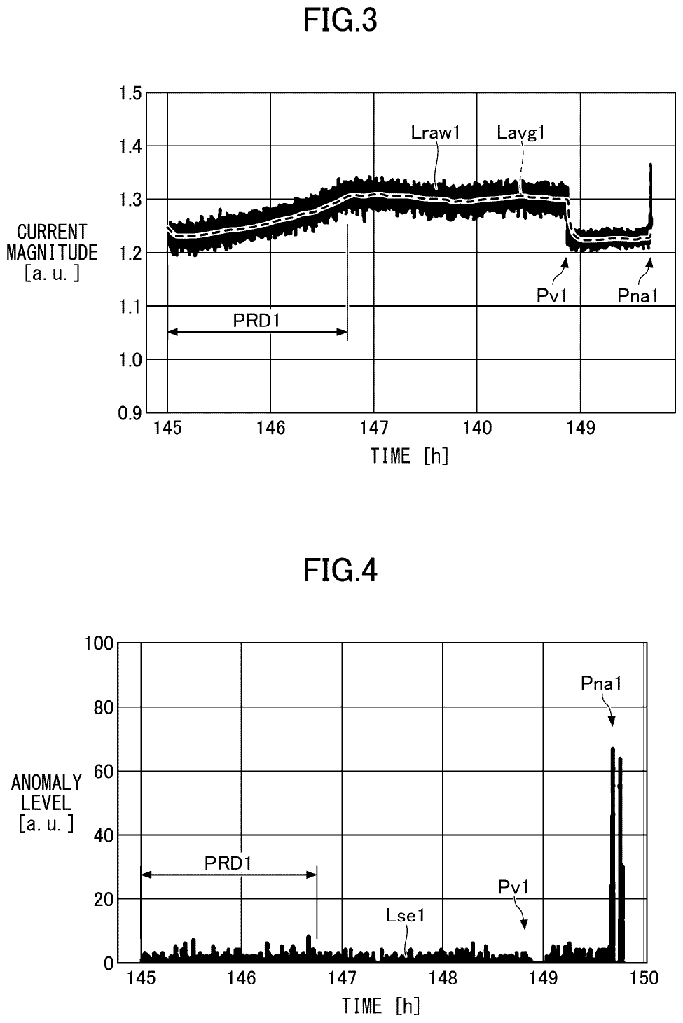

Hereinafter, operation results by the motor controller 100 that is an example of a motor controller according to the present embodiment will be described. FIGS. 3 and 4 are diagrams for describing the operation results by the motor controller 100, which is an example of the motor controller according to the present embodiment. In the operation results shown in FIGS. 3 and 4, the current magnitude of the power provided to the motor 10 is used as the characteristic value of the motor 10.

FIG. 3 is a diagram showing the current magnitude of the power provided to the motor 10. In FIG. 3, the horizontal axis represents the time elapsed from a predetermined time, and the vertical axis represents the current magnitude. The unit of time is hour (h), and the unit of current magnitude is arbitrary. FIG. 4 is a diagram showing a calculated anomaly level. In FIG. 4, the horizontal axis represents the time, and the vertical axis represents the anomaly level. The unit of time is hour (h), and the unit of anomaly level is arbitrary.

A line Lraw1 in FIG. 3 expresses the inspection data acquired by the anomaly detection controller 160. A line Lavg1 in FIG. 3 expresses the exponential moving average value of the inspection data processed by the anomaly detection controller 160. The exponential moving average value is calculated using Equation 7. In FIG. 3, N in Equation 7 is set to 100. A line Lse1 in FIG. 4 expresses the anomaly level calculated by the anomaly detection controller 160.

In each of FIGS. 3 and 4, an arrow Pv1 expresses the time at which the command speed transmitted to the motor 10 changes. In each of FIGS. 3 and 4, a period PRD1 is a time period during the inspection data gradually changes. In each of FIGS. 3 and 4, an arrow Pna1 expresses the time at which a malfunction has occurred in the motor.

[Case where Sudden Change is Made]

In a case in which a sudden change is made, for example, a case where a motor command speed is changed. operation results by the motor controller 100 will be described as follows.

As shown in FIG. 3, it can be seen that at the time point expressed by the arrow Pv1, the exponential moving average value expressed by the line Lavg1 changes following the inspection data expressed by the line Lraw1. In addition, as shown in FIG. 4, the anomaly level does not change significantly at the time point expressed by the arrow Pv1. On the other hand, the anomaly level is increased at the time point expressed by an arrow Pna1. As a result, the anomaly can be detected by comparing the anomaly level with a threshold.

[Case in which Gradual Change is Made]

The operation results by the motor controller 100 will be described in a case a gradual change is made.

As shown in FIG. 3, during the period PRD1, the inspection data gradually changes over time. Then, as shown in FIG. 3, it can be seen that the exponential moving average value expressed by the line Lavg1 changes following the inspection data expressed by the line Lraw1. Further, as shown in FIG. 4, in a range (period PRD1) in which the inspection data gradually changes, the anomaly level does not change significantly. On the other hand, at the time point expressed by the arrow Pna1, the anomaly level is increased. At a result, the anomaly can be detected by comparing the anomaly level with a threshold.

### [Standard Deviation of Characteristic Values]

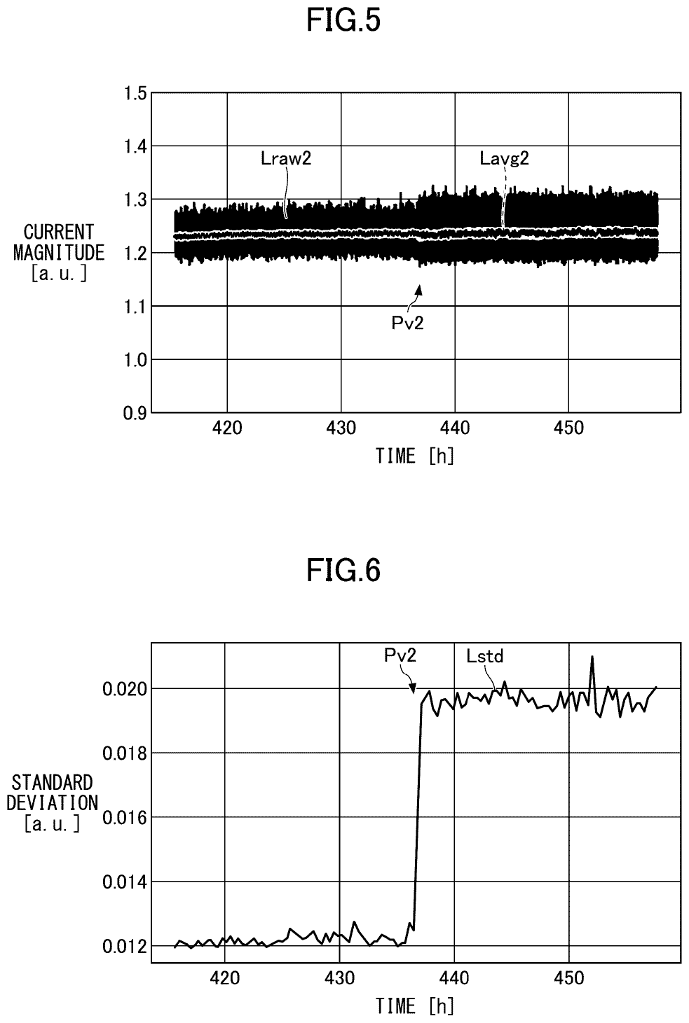

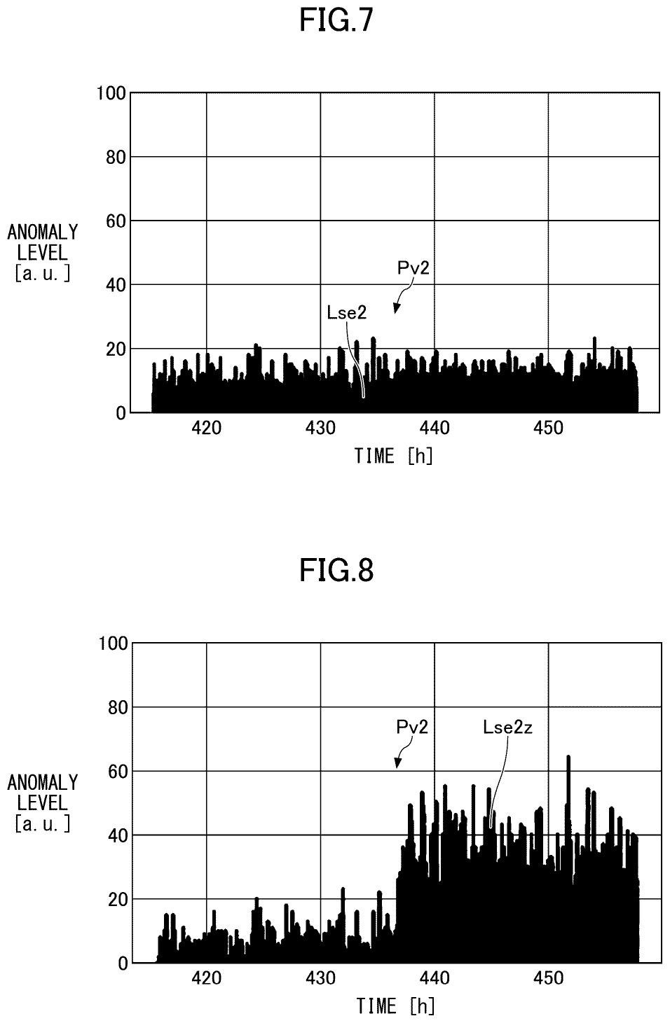

The characteristic values of the motor 10 operated by the motor controller 100 will be described below. The motor controller 100 is an example of the motor controller according to the present embodiment. FIGS. 5 to 7 are diagrams for describing operation results by the motor controller 100 that is an example of the motor controller according to the present embodiment. Specifically, FIG. 5 is a diagram showing the inspection data obtained when the motor controller 100 operates. FIG. 6 is a diagram showing a calculation result of the standard deviation of current magnitudes of the power provided to the motor 10 in a case where the inspection data in FIG. 5 is used in a predetermined interval. FIG. 7 is a diagram showing a calculation result of the anomaly level by the motor controller 100.

FIG. 5 is a diagram showing the current magnitude of the power provided to the motor 10. In FIG. 5, the horizontal axis represents the time elapsed from a predetermined time, and the vertical axis represents the current magnitude. The unit of time is hour (h), and the unit of current magnitude is arbitrary. A line Lraw2 in FIG. 5 expresses the inspection data acquired by the anomaly detection controller 160. A line Lavg2 in FIG. 5 expresses the exponential moving average value of the inspection data processed by the anomaly detection controller 160. The exponential moving average value is calculated using Equation 7. In FIG. 5, N in Equation 7 is set to 100.

At the time point expressed by an arrow Pv2 in FIG. 5, the motor 10 operates normally, but variations in the current increase due to a disturbance. In other words, FIG. 5 illustrates an example in which the standard deviation permanently changes due to the disturbance. FIG. 6 shows a calculation result of the standard deviation of the inspection data in FIG. 5 during a predetermined interval.

FIG. 6 shows the calculated standard deviation. A line Lstd in FIG. 6 expresses the calculated standard deviation. In FIG. 6, the horizontal axis represents the time, and the vertical axis represents the standard deviation of the current magnitudes. The unit of time is hour (h), and the unit of the standard deviation of the current magnitudes is arbitrary. As shown in FIG. 6, the standard deviation rapidly increases as expressed by an arrow Pv2. On the other hand, in FIG. 6, the average of the current magnitudes is substantially constant.

FIG. 7 shows a result obtained by processing the inspection data shown in FIG. 5 through the motor controller 100. A line Lse2 in FIG. 7 expresses the anomaly level calculated by the anomaly detection controller 160. In FIG. 7, the horizontal axis represents the time, and the vertical axis represents the anomaly level. The unit of time is hour (h), and the unit of anomaly level is arbitrary.

As shown in FIG. 7, there is no significant change in the anomaly level before and after the time point expressed by the arrow Pv2, in other words, before and after a change in the standard deviation of the inspection data. That is, false detection in the anomaly of the motor can be suppressed by dynamically calculating the standard deviation by the motor controller 100.

A result obtained when the standard deviation is set to a fixed value will be described below. FIG. 8 is a diagram for describing the operation result by the motor controller in a reference example in which the standard deviation is set to a fixed value. A line Lse2z expresses the calculated anomaly level in a case where the standard deviation is set to the fixed value.

As shown in FIG. 8, when the standard deviation of the inspection data is set to the fixed value, the anomaly level is increased at the time point expressed by the arrow Pv2. In this case, the motor controller in the reference example may erroneously detect the anomaly of the motor.

In the motor controller according to the present embodiment, the anomaly level is calculated by dynamically changing the standard deviation. With this arrangement, even if the standard deviation permanently changes due to a disturbance, false detection, in which the resulting anomaly level is increased when performing anomaly detection of the motor, can be suppressed.

### [Smoothing Factor N]

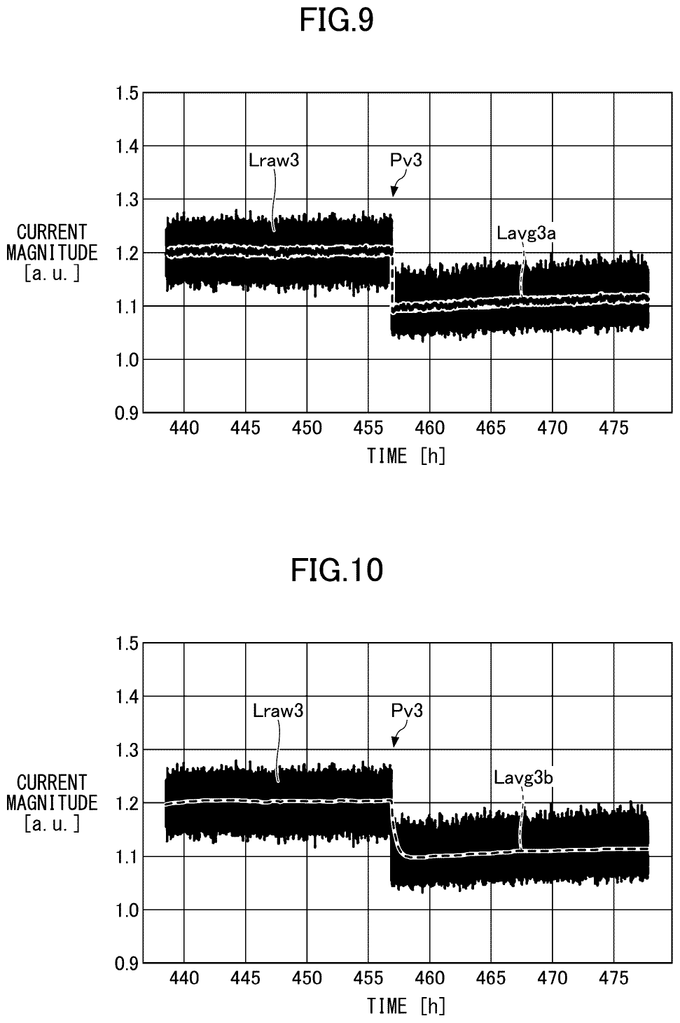

A smoothing factor N obtained when the motor controller 100 that is an example of the motor controller of the present embodiment operates will be described below. FIGS. 9 and 10 are diagrams for describing operation results by the motor controller 100 that is an example of the motor controller of the present embodiment. Specifically, FIG. 9 shows a calculation result in a case where the smoothing factor N is set to 100 and the inspection data largely changes at a predetermined time (expressed by an arrow Pv3). FIG. 10 shows a calculation result in a case where the smoothing factor N is set to 5000 with respect to the inspection data in FIG. 9.

FIGS. 9 and 10 show calculated exponential moving average values. In each of FIGS. 9 and 10, the horizontal axis represents the time, and the vertical axis represents the current magnitude. The unit of time is hour (h), and the unit of current magnitudes is arbitrary.

As shown in FIG. 9, when the smoothing factor N is 100, the exponential moving average value expressed by a line Lavg3a appropriately follows the inspection data.

As shown in FIG. 10, when the smoothing factor N is 5000, it takes time for the exponential moving average value expressed by a line Lavg3b to follow the inspection data.

From the above results, the smoothing factor N is appropriately determined in accordance with the change level of the characteristic value, so as to detect an anomaly. For example, the smoothing factor N may be determined in the range of greater than or equal to 100 and less than or equal to 1,000.

### SUMMARY

In the motor controller according to the present embodiment, false detection can be suppressed when performing anomaly detection of the motor.

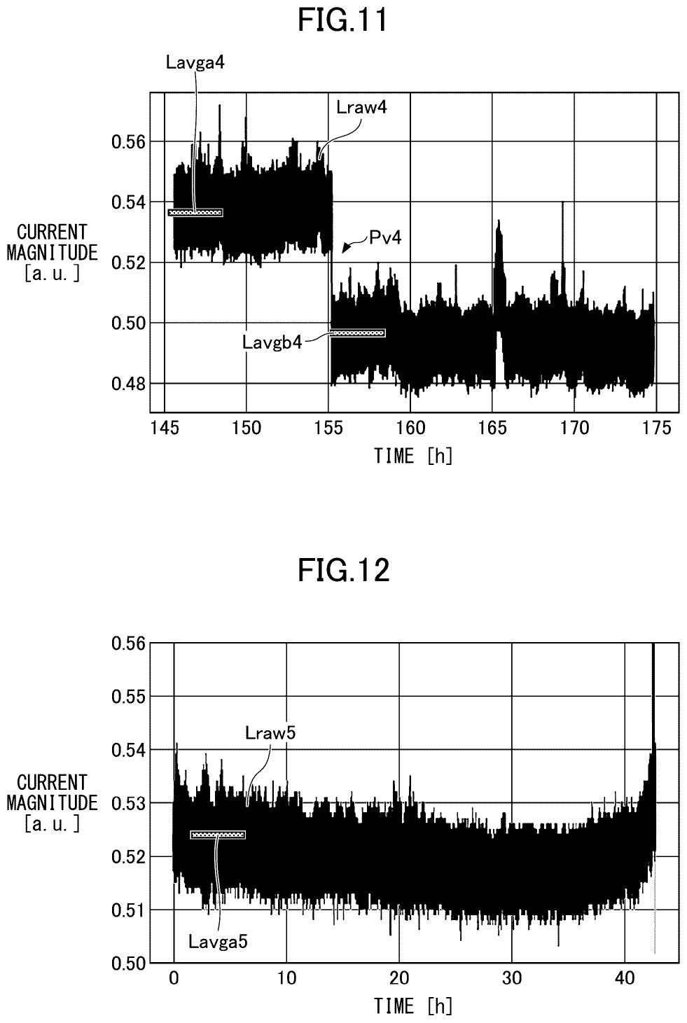

For example, the motor controller in the reference example will be described with reference to FIG. 11 by using a case example where there is a sudden change.

As the motor controller in the reference example, for example, an average value of inspection data expressed by a line Lraw4 is first calculated as expressed by a line Lavga4 in FIG. 11. When the average value of the inspection data is calculated as expressed by the line Lavga4 in FIG. 11, the sudden change cannot be reflected in the average value unless a new average value of the inspection data is calculated again as expressed by the line Lavgb4, at the time point expressed by an arrow Pv4.

Further, for example, the motor controller in the reference example will be described with reference to FIG. 12 by using a case example in which there is a gradual change.

As the motor controller in the reference example, for example, as shown as line Lavga5 in FIG. 12, when an average value of inspection data is first calculated based on inspection data expressed by a line Lraw5, a dissociation between the inspection data and the average value is increased over time.

In the motor controller according to the present embodiment, even when the characteristic value changes suddenly or gradually, false detection can be suppressed when performing anomaly detection of the motor.

For example, when the current magnitude is used as the characteristic value, the current measuring unit 140 is used as an example of an acquisition unit that acquires the characteristic value related to the motor. The anomaly detection controller 160 is an example of a processor that processes a characteristic value that is acquired by an acquisition unit.

### <Modifications>

In step S50, a change level Sd2(n) is calculated instead of the change level Sd(n), and an anomaly level Se2(n) may be calculated as an anomaly level, instead of the anomaly level Se(n). In other words, the anomaly detection controller 160 may detect a downturn in the characteristic value using a cumulative sum method. The anomaly detection controller 160 calculates the change level Sd2(n) as expressed in Equation 10.

$$\begin{matrix}[ Math . 10 ] & \\ Sd 2 ( n ) = \frac{R i ( n ) ( x i ( n ) - y i ( n - 1 ) + \frac{R i ( n )}{2} )}{σ {i ( n )}^{2}} & Equation 10\end{matrix}$$

Then, the anomaly detection controller 160 calculates the anomaly level Se2(n) as expressed in Equation 11.

$$\begin{matrix}[ Math . 11 ] & \\ Se 2 ( n ) = max \{ 0 , Se 2 ( n - 1 ) - Sd 2 ( n ) \} & Equation 11\end{matrix}$$

Here, max{a,b} is a function that returns a greater value of a and b. That is, max{0, Se2(n−1)-Sd2(n)} returns zero when “Se2(n−1)-Sd2(n)” is negative or zero, and max{0, Se2(n−1)-Sd2(n)} returns Se(n−1)-Sd2(n) when “Se2(n−1)-Sd2(n)” is positive.

In the above-described embodiment, the current magnitude of the current that is provided to the motor 10 is used as input data indicating an operating state of the motor 10, but the input data is not limited to the current magnitude. For example, any one among the voltage magnitude of the power provided to the motor, the number of revolutions of the motor 10, and a duty cycle may be used as the input data.

Although the motor controller is described with reference to the above embodiments, the present disclosure is not limited to the embodiments. Various modifications and improvements, such as combination with or replacement with some or all of the other embodiments can be made within the scope set forth in the present disclosure.

In a motor anomaly detector in the present disclosure, false detection can be suppressed when performing anomaly detection of a motor.

What is claimed is:

1. An anomaly detector for detecting an anomaly of a motor, the anomaly detector comprising:
circuitry configured to
acquire a characteristic value related to the motor, and
process the characteristic value,
wherein the circuitry is configured to
acquire the characteristic value related to the motor as inspection data,
update a statistic of the inspection data,
update an amplitude from an updated statistic,
update an exponential moving average value of the inspection data,
update an anomaly level based on the inspection data, the amplitude, the statistic, and the exponential moving average value, and
detect the anomaly of the motor based on the anomaly level.

2. The anomaly detector according to claim 1, wherein the characteristic value includes any one among a current magnitude or a voltage magnitude of power that is provided to the motor; a rotational speed of the motor; and a duty cycle of a signal to drive the motor.

3. The anomaly detector according to claim 1, wherein the statistic includes a standard deviation of the inspection data,
wherein the circuitry is configured to
multiply a first value by the amplitude, the first value being obtained by subtracting half of the amplitude from a difference between the inspection data and the exponential moving average value, and
divide, by a square of the standard deviation, a second value obtained by multiplying the first value by the amplitude to determine a change level, and
wherein the circuitry is configured to
update the anomaly level to a third value obtained by adding the change level to the anomaly level, upon occurrence of a condition in which the third value is greater than or equal to zero, and
update the anomaly level to zero, upon occurrence of a condition in which the third value is less than zero.

4. The anomaly detector according to claim 1, wherein the statistic includes a standard deviation of the inspection data, and
wherein the circuitry is configured to
multiply a first value by the amplitude, the first value being obtained by adding half of the amplitude to a difference between the inspection data and the exponential moving average value, and
divide, by a square of the standard deviation, a second value obtained by multiplying the first value by the amplitude to determine a change level, and
wherein the circuitry is configured to
update the anomaly level to a third value obtained by subtracting the change level from the anomaly level, upon occurrence of a condition in which the third value is greater than or equal to zero, and
update the anomaly level to zero, upon occurrence of a condition in which the third value is less than zero.

5. The anomaly detector according to claim 1,
wherein the circuitry is configured to divide the sum of the inspection data and a first value by a second value, the first value being obtained by multiplying the exponential moving average value by a smoothing factor, and the second value being obtained by adding 1 to the smoothing factor, and
update the exponential moving average value to a third value obtained by dividing the sum of the inspection data and the first value by the second value.

6. The anomaly detector according to claim 5, wherein the smoothing factor is greater than or equal to 100 and less than or equal to 1,000.

7. A motor system comprising:
a motor;
an anomaly detector for detecting an anomaly of the motor, the anomaly detector including circuitry configured to
acquire a characteristic value related to the motor, and
process the characteristic value,
wherein the circuitry is configured to
acquire the characteristic value related to the motor as inspection data,
update a statistic of the inspection data,
update an amplitude from an updated statistic,
update an exponential moving average value of the inspection data,
update an anomaly level based on the inspection data, the amplitude, the statistic, and the exponential moving average value, and
detect the anomaly of the motor based on the anomaly level.

8. A method for detecting an anomaly of a motor, comprising:
acquiring a characteristic value related to the motor as inspection data;
updating a statistic of the inspection data;
updating an amplitude from an updated statistic;
updating an exponential moving average value of the inspection data;
updating an anomaly level based on the inspection data, the amplitude, the statistic, and the exponential moving average value; and
detecting the anomaly of the motor based on the anomaly level.
